(19) United States
(12) Patent Application Publication
(10) Pub. No.: US 2006/0108688 A1
(43) Pub. Date: May 25, 2006

(54) Large grained polycrystalline silicon and method of making same

(75) Inventors: Christine Esber Richardson, Pasadena, CA (US); Harry A. Atwater, South Pasadena, CA (US)

Correspondence Address: FOLEY AND LARDNER LLP;SUITE 500, 3000 K STREET NW, WASHINGTON, DC, 20007, US

(73) Assignee: CALIFORNIA INSTITUTE OF TECHNOLOGY

(21) Appl. No.: 11/274,197

(22) Filed: Nov. 16, 2005

Related U.S. Application Data
(60) Provisional application No. 60/629,676, filed on Nov. 19, 2004.

(51) Int. Cl. H01L 23/48

(52) U.S. Cl. 257/756; 257/750; 257/753

(57) ABSTRACT

A silicon structure includes a selective nucleating single phase epitaxial (SNSPE) template polysilicon layer containing crystallization catalyst residue, and a hot wire chemical vapor deposited (HWCVD) epitaxial polysilicon layer epitaxially grown on said template layer. The silicon structure may satisfy at least one of the following: 1) a thickness of the SNSPE template layer is less that about 60 nm; 2) a thickness of the HPCVD layer is greater than about 60 nm. The silicon structure may be used in a polysilicon solar cell or other solid state devices. A method of making a polysilicon layer includes providing a first layer comprising an amorphous silicon or a polysilicon layer containing a crystallization catalyst or in contact with a crystallization catalyst, and annealing the first layer in a silicon containing atmosphere to at least partially crystallize the first layer.

### CROSS-REFERENCE TO RELATED PATENT APPLICATIONS

This application claims priority to U.S. provisional application No. 60/629,676 “Fabrication process for Large-Grained Polycrystalline Thin Film Solar Cells” to Richardson et. al. filed Nov. 19, 2004, which is incorporated herein by reference in its entirety.

### STATEMENT REGARDING FEDERALLY SPONSORED RESEARCH OR DEVELOPMENT

This invention was made with government support under grant number DE-AC36-99G010337 from the NREL. The United States government may have rights in this invention.

### FIELD OF THE INVENTION

The present invention is generally directed to large-grain polycrystalline silicon, methods of fabricating large-grain polycrystalline silicon and electronic devices comprising large-grain polycrystalline silicon, such as thin film solar cells.

### BACKGROUND OF THE INVENTION

The worldwide demand for photovoltaic power modules has grown over the last several years. However, the price per watt of the electricity generated by these modules is higher than desired due to the high energy costs of refining silicon into ingots for use in traditional solar cells. Moreover, a substantial amount of material is lost once the ingots are sawed into wafers.

### SUMMARY

A silicon structure includes a selective nucleating single phase epitaxial (SNSPE) template polysilicon layer containing crystallization catalyst residue, and a hot wire chemical vapor deposited (HWCVD) epitaxial polysilicon layer epitaxially grown on said template layer. The silicon structure may satisfy at least one of the following: 1) a thickness of the SNSPE template layer is less that about 500 nm; 2) a thickness of the HWCVD layer is greater than about 60 nm. The silicon structure may be used in a polysilicon solar cell or other solid state devices. A method of making a polysilicon layer includes providing a first layer comprising an amorphous silicon or a polysilicon layer containing a crystallization catalyst or in contact with a crystallization catalyst, and annealing the first layer in a silicon containing atmosphere to at least partially crystallize the first layer.

### BRIEF DESCRIPTION OF THE DRAWINGS

FIG. 1 is a side cross sectional view of one possible embodiment of a polycrystalline silicon solar cell.

FIGS. 2A-D illustrate the selective nucleation and solid phase epitaxy (SNSPE) process.

FIG. 3 illustrates the hot-wire chemical vapor deposition (HWCVD) process.

FIGS. 4A-D show optical microscope images of SNSPE templates.

FIG. 5A-D show atomic force microscopy images of SNSPE templates.

FIGS. 6A-C compare diffraction patterns of HWCVD silicon thin films grown on SNSPE templates in the presence of SiH₄ and in vacuum.

### DETAILED DESCRIPTION

In a first embodiment of the invention the inventors found that epitaxial polysilicon layer with a thickness of more than 60 nm may be epitaxially grown on a relatively thin polysilicon template material with a thickness of less than 500 nm, such as less than 60 nm for example. In a second embodiment of invention, the inventors found that catalyst mediated recrystallization of amorphous or polycrystalline silicon may be conducted at a lower temperate to produce a higher quality polysilicon layer when the recrystallization is conducted in a silicon containing ambient or atmosphere. The recrystallized silicon layer of the second embodiment may be used as the template material to grow the epitaxial polysilicon layer of the first embodiment.

### FIRST EMBODIMENT

The first embodiment provides a silicon structure comprising (a) a polysilicon template layer and (b) an epitaxial polysilicon layer formed on the template. The template is preferably a so-called selective nucleation single phase epitaxial (SNSPE) template comprising crystallization catalyst residue. In other words, the template comprises a polysilicon layer which is formed by the so-called selective nucleation and solid phase epitaxy (SNSPE), which is also known as metal induced crystallization (MIC) or catalyst mediated crystallization method. In the SNSPE or MIC process, an amorphous silicon (a-Si) or a relatively small grain polysilicon layer is formed on a substrate. This layer is then contacted with a crystallization promoting catalyst material. This may be done by forming the catalyst on the layer, by forming the layer on the catalyst or by introducing the catalyst into the layer. For example, the catalyst may comprise catalyst particles which are formed over or under the silicon layer by spin coating or other deposition methods. Alternatively, the catalyst may comprise a catalyst layer which is formed over or under the layer by sputtering, CVD or other deposition methods. The catalyst layer may be patterned into a pattern of discreet nucleating seed regions or it may be a continuous layer. Alternatively, the catalyst may be implanted or diffused into the entire silicon layer or into discreet seed regions in the silicon layer. Alternatively, the catalyst may be introduced into the silicon layer from the gas phase during the silicon layer deposition.

The amorphous or polycrystalline silicon layer is then annealed and grains nucleate from the regions contacting the catalyst. Preferably, the catalyst material is present in the silicon layer, either by solid state diffusion from deposited catalyst which contacts the silicon layer, by implantation, by gas phase diffusion or by co-deposition of the catalyst and the silicon layer. The catalyst material in the silicon layer nucleates grains and promotes grain growth by leading a crystallization front through the amorphous silicon or small grain polysilicon layer, leaving behind large crystalline grains. The grain's growth terminates when two catalyst containing crystallization fronts impinge on each other (i.e., when one growing grain contacts an adjacent grain). Thus, a catalyst material residue remains in the recrystallized polysilicon layer.

The catalyst preferably comprises a metal or a metal silicide which can promote the crystallization of silicon at a lower temperature, such as Ni (nickel), Fe (iron), Co (cobalt), Ru (ruthenium), Rh (rhodium), Pd (palladium), Os (osmium), Ir (iridium), Pt (platinum), Cu (copper), Al (aluminum), In (indium), Au (gold) and alloys and silicides thereof. Germanium may also be used instead of metal. The preferred catalyst material is Ni. SNSPE or metal induced crystallization (MIC) is generally known to ones of ordinary skill in the art. SNSPE or MIC is described, for example, in:
1) Chen, C. M., Polycrystalline Silicon Thin Films for Photovoltaics, Ph.D. Thesis, 2001, California Institute of Technology, incorporated hereby reference in its entirety;
2) Puglisi, R. A., et. al. Material Science and Engineering B73 (2000) 212-217, incorporated hereby by reference in its entirety;

The epitaxial polysilicon layer may be formed on the template layer by any suitable method, such as by CVD. Preferably, the polysilicon layer is epitaxially grown by hot wire chemical vapor deposition. The HWCVD epitaxial film can have the same crystalline structure as the SNSPE template. In other words the grains and the grain boundaries in the template layer generally line up with the grains and grain boundaries in the epitaxial layer. The comparison of crystalline structures can be carried out, for example, by a diffraction technique such as reflective high energy electron diffraction (RHEED) or other appropriate method known to ordinary artisan. Use of RHEED for determining the crystallinity and/or to verify the epitaxial character of HWCVD grown films can be found in, for example, M. Swiatek Mason, et. al. National Center for Photovoltaics and Solar Program Review Meeting 2003 Proceedings p. 748-749; C. E. Richardson et. al. MRS Proceedings, Spring 2004, Volume 808, A8.11, H. A. Atwater, 2002 Annual Technical Report to the Midwest Research Institute National Renewable Energy Laboratory, Subcontract DE-AC36-99G010337 “Thin film Silicon Cells on Low-Cost Substrates”, incorporated hereby by reference in their entirety.

The silicon structure of the first embodiment can be used in a variety of applications including electronic and optoelectronic devices such as a field effect transistor or a photovoltaic (i.e., solar) cell.

The transistor may comprise a thin film transistor (TFT), in which the template layer alone and/or the template layer and the epitaxial layer comprise the active layer of the TFT. The active layer is formed over an insulating substrate, such as glass, plastic or quartz substrate or an semiconductor or conducting substrate covered with insulating layer, such as silicon dioxide. Source and drain regions are formed in the active layer to circumscribe the channel region between then and a gate electrode is formed over or under the channel.

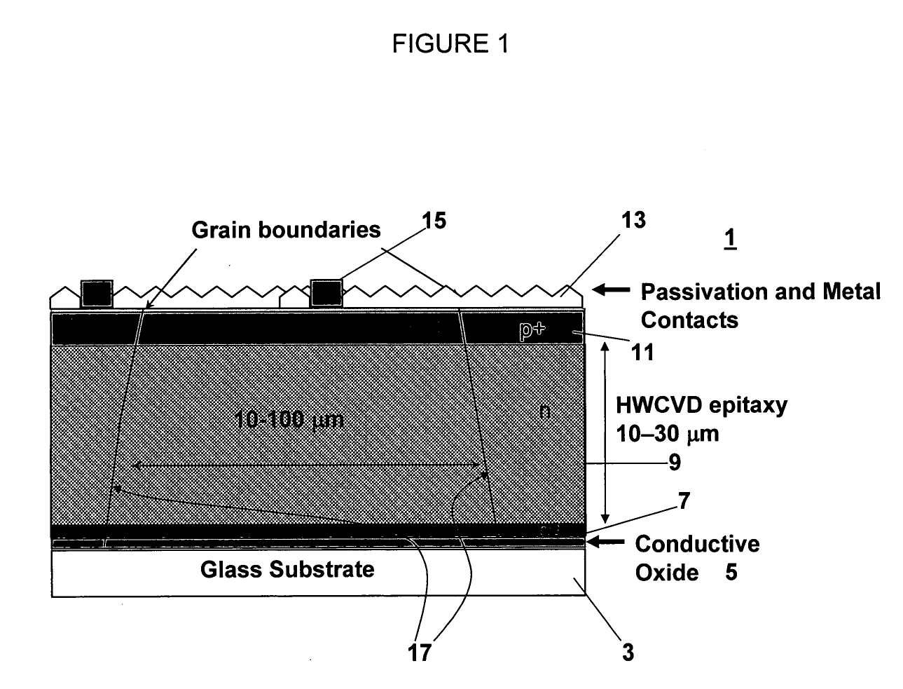

The photovoltaic (solar) cell 1 comprising the silicon structure of the first embodiment is illustrated in FIG. 1. The photovoltaic cell of FIG. 1 comprises a transparent substrate 3, such as a glass substrate, a transparent conductive oxide (i.e., a first electrode) 5 coated on the substrate, a SNSPE polysilicon template layer 7, which can serve as the n⁺ layer of the cell, a HWCVD n-type epitaxial layer 9 epitaxially grown on the n+ template 7 and a p⁺ epitaxial layer 11 formed on the n-type layer 9. The cell also comprises a passivation layer 13 and metal contacts 15 (i.e., second electrode). If desired the HWCVD layer 9 may comprise a p-type layer to form a p-n junction at the interface of layers 7 and 9. The p-type and n-type conductivities of the layers can be reversed. As shown in FIG. 1, the grain boundaries 17 generally line up through layers 7, 9 and 11. If desired, an antireflective coating may also be added above layer 11.

In the first embodiment, the silicon structure satisfies at least one of the following: 1) a thickness of the SNSPE template layer 7 is less that about 60 nm, such as about 10 nanometers to about 50 nanometers; and/or 2) a thickness of the first HPCVD layer 9 is greater than about 60 nm.

In other embodiments, the thickness of the SNSPE template layer 7 can range from about 10 nanometers to about 1000 nanometers, or from about 10 nanometers to about 500 nanometers, or from about 10 nanometers to about 200 nanometers, or from about 10 nanometers to about 100 nanometers, or.

The thickness of the first HWCVD layer 9 can range from about 70 nanometers to about 100 microns, or from about 100 nanometers to about 50 microns, or from about 200 nanometers to about 30 microns, or from about 1 micron to about 30 microns, or from about 10 microns to about 30 microns, as illustrated in FIG. 1. The particular thickness can be chosen by one of ordinary skill in the art depending on the application.

The silicon structure 1 can comprise multiple HWCVD epitaxial layers 9, 11 each having the same crystalline structure as the SNSPE template layer 7. Each subsequent HWCVD layer can use underlying HWCVD layer as a template for epitaxial growth.

The crystallization catalyst residue in the template layer 7 can comprise Ni, Fe, Co, Ru, Rh, Pd, Os, Ir, Pt, Cu, Au, In, Ge, Al or any combination thereof. In the preferred embodiment, the crystallization catalyst residue can comprise Ni.

The grain size of crystalline silicon grains in layers 7, 9 and 11 comprises average grain size and can depend on the crystallization catalyst and conditions used. The grain size can be greater than about 1 micron, or greater than about 5 microns, or greater than about 10 microns. The exemplary range of the grain size can be from about 1 microns to about 200 microns, from about 5 microns to about 150 microns, or from about 10 microns to about 100 microns.

The crystalline silicon grains can amount for at least about 50% of the SNSPE template layer 7, such between 80% and 100% of the SNSPE template. The template layer 7 may have the same grain size as the epitaxial layer 9 described above. The percentage of crystalline silicon grains in the SNSPE template can be determined by any appropriate technique known to ordinary artisan. One non-limiting example of such technique can be Raman spectroscopy, where silicon crystallinity can be determined by comparing intensities of Raman modes at ˜520 cm⁻¹ and ˜480 cm⁻¹ corresponding to crystalline and amorphous silicon respectively.

The SNSPE template layer 7 can have an average surface roughness of at least 15 Å, such as at least 25 Å, for example least 30-35 Å, and an atomic force microscopy (AFM) determined root-mean-square (RMS) roughness of 10 micron square AFM scan of at least 25 Å, such as 40-45 Å, for example. The relatively high roughness can allow the use of a thinner HWCVD layer 9, such as a less than 2 um thick layer, as an absorber. The higher roughness can increase the probability of light trapping which can allow the use of a thinner active layer(s).

The SNSPE template layer 7 can be disposed or grown over a substrate 3 comprising at least one material with a melting or softening (i.e., transition temperature) temperature below about 600° C. The example of a material with a melting or softening temperature below 600° C., such as 550 to 500° C. and below, can be ordinary glass such as soda lime glass or borosilicate glass which have softening temperatures of 550° C. and 500° C. respectively. The SNSPE layer can also be easily grown on a substrate with a softening temperature above 600° C. such as a metal or high temperature glass.

The transparent electrode 5 may comprise a transparent conducting oxide. Non-limiting examples of conducting oxides include doped and undoped form of zinc oxide (ZnO), tin oxide (SnO₂), cadmium oxide (CdO), indium oxide (In₂O₃), magnesium oxide (MgO₂), indium tin oxide (InₓSnₓO₂), CuAlO₂, Cu₂SrO₂, CdSnO₄, Zn₂SnO₄, MgIn₂O₄, CdSb₂O₆:Y, ZnSnO₃, GalnO₃, Zn₂In₂O₅, and In₄Sn₃O₁₂. Stoichiometric formulas of the oxide are used only for illustration, and non-stoichiometric conducting oxides can be used as well. In the preferred embodiment, the conducting oxide can be commercially available conducting oxide, such as tin oxide, or a conducting oxide that can be produced in a high volume manufacturing process. This electrode is not necessary in an embodiment that would include back contacts only as is well understood by one of ordinary skill in the art.

The passivation layer 13 may comprise silicon nitride or any other suitable passivation material. The electrode 15 can comprise electrically conducting material, such as metal. For example, the conducting material may comprise Al, Ti, Pt, Au, Pd, Cr, Cu, and/or Ag.

### SECOND EMBODIMENT

A second embodiment of invention comprises a method of making polycrystalline silicon structure, comprising annealing in a silicon containing atmosphere an amorphous silicon or polycrystalline silicon layer contacting or containing a crystallization catalyst. The anneal crystallizes the layer (i.e., crystallizes the amorphous silicon or recrystallizes a small grain size polysilicon) to form a polysilicon layer with a large grain size, such as an average grain size of 10-100 microns. This recrystallized layer may then be used as the template layer 7 for epitaxial CVD layer 9 formation of the first embodiment.

Any suitable silicon containing atmosphere may be used during the crystallization anneal. Preferably, the silicon containing atmosphere comprises a silane atmosphere. However, other silicon bearing gases may be used instead of or in addition to silane. For example, silicon and chlorine bearing gases may be used, such as silicon tetrachloride (SiCl₄), thrichrosilane (SiHCl₃), dichlorosilane (SiH₂Cl₂) or any mixture thereof. The silicon containing atmosphere can further comprise a carrier gas such hydrogen, nitrogen, forming gas, inert gas (i.e., noble gas) such as argon, or a mixture thereof.

The present inventors found that the crystallization anneal can be performed in a silicon containing atmosphere at a temperature below about 550° C., such as below 500° C. Performing annealing at these low temperatures can be advantageous as it allows one to use inexpensive glass and plastic substrates comprising a low melting/softening point, including ordinary window glass which can be extremely advantageous for mass production of solar cells.

The amorphous silicon or small grain polysilicon (including microcrystalline) template layer 7 can be deposited on a substrate using any appropriate technique, such as chemical vapor deposition technique, including low pressure chemical vapor deposition or hot wire chemical vapor deposition.

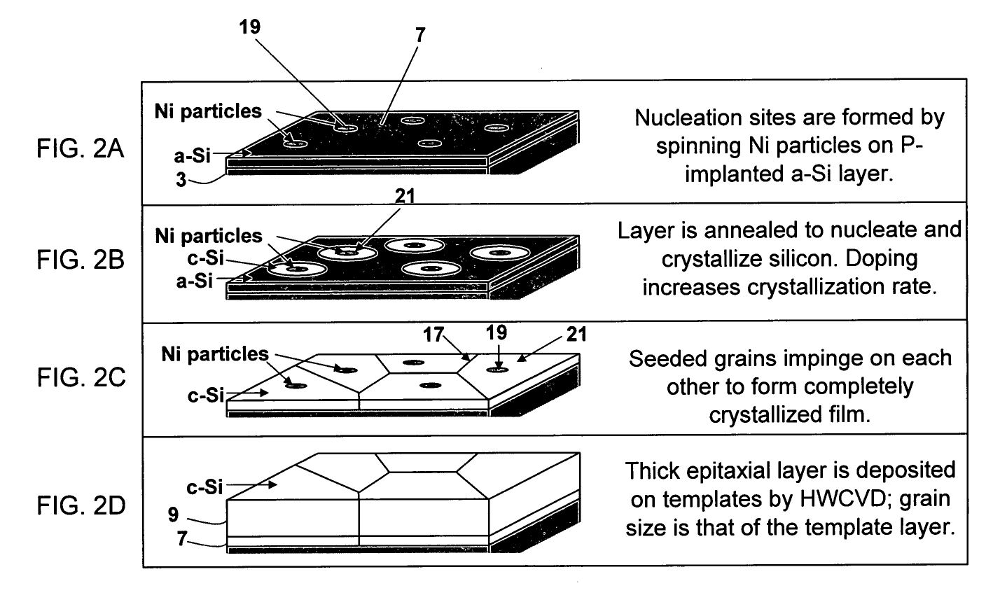

As described above, the catalyst material may be formed in contact with and/or introduced into layer 7 by any suitable method described above. As shown in FIG. 2A, nickel nanoparticles 19 are spin-coated on an amorphous silicon layer 7. This layer 7 may be p-type doped or n-type doped to increase the crystallization rate or it may be undoped. For example, layer 7 may comprise a phosphorus implanted amorphous silicon layer. Then, the layer 7 is annealed in a silane atmosphere at a temperature of 450 to 600 C, such as 450 to 500 C to nucleate and crystallize the silicon. As shown in FIG. 2B, crystallized silicon regions (i.e., grains) 21 begin to grow around the nanoparticles 19. The grains 21 impinge on each other to form a crystallized layer 7, as shown in FIG. 2C. The grain boundaries 17 may contain nickel (i.e., catalyst) residue. The silane may be provided from a gas tank to an annealing furnace or the anneal may be conducted in the silicon deposition chamber with the silane provided from a silicon gas source. The anneal may be conducted for any suitable amount of time to achieve a sufficient amount of crystallization, such as for example between 3 hours and 24 hours, including between 5 and 10 hours to achieve between 20% and 99% crystallization, such as 50 to 85% crystallization.

If desired, the deposited layer 7 can be exposed to HF solution or other oxide removal agents to remove native oxide from amorphous silicon prior to introducing the crystallization catalyst particles. In this case, after introduction of the crystallization catalyst particles 19, amorphous silicon can be immediately annealed before an oxide has a chance to reform.

If desired, after annealing, the annealed layer 7 containing crystalline catalyst residue can be exposed to a cleaning procedure. Appropriate cleaning procedures are generally known to one of ordinary skill in the art. For example, if removing of unnecessary crystalline residue is desired, then the annealed layer 7 can be treated with a heated “piranha” solution H₂SO₄:H₂O₂ (4:1). If desired, the layer may be annealed in a chlorine ambient to remove some of the nickel residue from the layer 7. To remove the Ni particles a dip in 3:7 HNO3:H2O can be performed. The rest is trapped in a silicide.

The method of making polycrystalline structure can further comprise depositing on the template layer 7 one or more epitaxial layers 9, 11, wherein each of said epitaxial layers has the same crystalline structure as said template layer 7, as shown in FIG. 2D. The epitaxial layer(s) can be deposited by a variety of methods. Preferably, the epitaxial layers are deposited by HWCVD. In case of multiple epitaxial layers deposited, each of the layers can be different. For example, for solar cell applications, it can be desirable to deposit an epitaxial layer of n-doped silicon 9 on the template layer 7 containing the crystallization catalyst residue and then deposit an epitaxial layer of p-doped silicon 11 using the n-doped silicon epitaxial layer 9 as a template. Alternatively, the p-doped layer can be of a different structure such as a-Si for passivation.

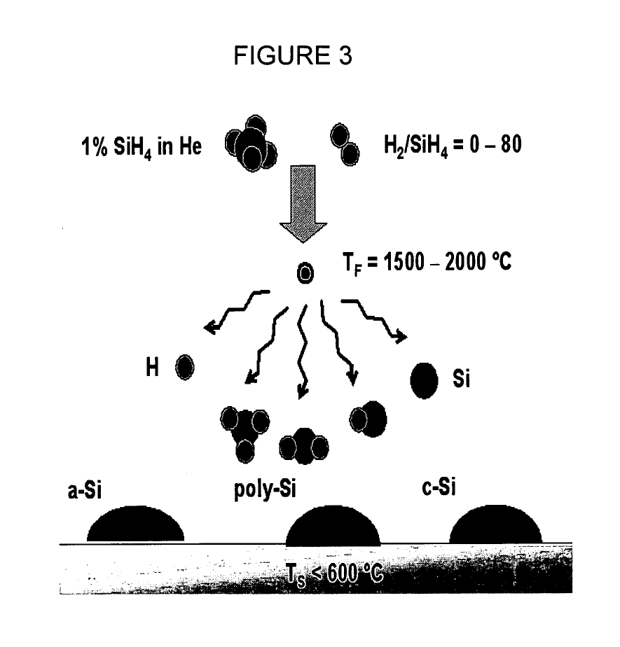

HWCVD of silicon layers involves the decomposition of gas precursors on a heated refractory metal filament producing radical species which react in the gas phase and deposit a layer onto a heated substrate, as shown in FIG. 3. The resulting structure of HWCVD layer can be controlled by controlling several parameters, such as the filament temperature and material, growth pressure, gas flow rates and substrate temperature. HWCVD is generally known by ones of ordinary skill in the art, see e.g. 1) J. K. Rath, Solar Energy Materials & Solar Cells 76 (2003) 431-487, incorporated hereby by reference in its entirety; 2) Maribeth Swiatek Mason “Synthesis of Large-Grained Polycrystalline Silicon by Hot-Wire Chemical Vapor Deposition for Thin Film Photovoltaic Applications” Ph.D. Thesis, Calif. Institute of Technology, Pasadena, Calif., 2004, incorporated hereby by reference in its entirety, and, in particular, chapter 2, pages 7-10, discussing HWCVD and its applications for thin-film photovoltaics.

To achieve epitaxial growth using HWCVD, the deposition rate can be low. For example, the deposition rate can be lower than about 20 nm/min, such as lower than about 10 nm/min. The exemplary deposition rate can range from about 0.1 nm/min to about 8 nm/min To promote epitaxial growth, a silicon containing precursor gas used together with hydrogen. Hydrogen passivates the low angle grain boundaries in the deposited silicon layer. Passivation with hydrogen during the HWCVD process can be allow for millisecond minority carriers lifetimes in the deposited polysilicon layer, which is similar to bulk silicon. The silicon containing precursors include silicon tetrachloride (SiCl₄), thrichrosilane (SiHCl₃), dichlorosilane (SiH₂Cl₂), and silane (SiH₄). The preferred silicon containing precursor for HWCVD is silane. The hydrogen to silicon containing precursor ratio can range from about 500:1 to 0.1:1, or from about 80:1 to about 1:1, or from about 60:1 to about 10:1. The exemplary hydrogen to silicon containing precursor ratio can be about 50:1. The silicon containing precursor can be provided in mixture with a carrier gas such as nitrogen, helium, neon, argon or any combination thereof. The concentration of the silicon containing precursor in the carrier gas can range from about 0.001% to about 100%, or from 0.01% to about 10%, or from about 0.1% to about 5%. The exemplary concentration of silicon containing precursor in the carrier gas can be about 1%. The total pressure can range from about 10 to about 200 mTorr, or from about 50 to about 200 mTorr, or from about 75 to about 125 mTorr. When epitaxial deposition of doped silicon is desired, the mixture can further contain dopant precursor, such as a dopant hydride. The dopant precursors are generally known to ordinary artisan, see in S. Wolf and R. Tauber “Silicon Processingfor the VLSI Era”, volume 1, “Process Technology”, Lattice Press, Sunset Beach, Calif., 1986, incorporated herein by reference in its entirety, including, in particular, pages 137-138. The particular examples of the dopant precursors include diborane (B₂H₆) or trimethylboride to incorporate boron, phosphine (PH₃) to incorporate phosphorous, arsine (AsH₃) to incorporate arsenic and ammonia (NH₄) to incorporate nitrogen.

When multiple epitaxial films are deposited, it can be advantageous to deposit them without breaking vacuum. For example, if n layer 9 and then p⁺ layer 11 of silicon are deposited as illustrated on FIG. 1 without breaking vacuum, the efficiency of the photovoltaic cell can be significantly higher.

To form the solar cell 1, an ordinary sheet glass with a softening temperature of approximately 500-540 C may be used as a substrate 3. This substrate 3 can then to be coated with a conducting oxide layer 5, such as ZnO or doped-SnO₂. These substrates are commercially available, and can also be produced internally in a high volume manufacturing process.

The conductive oxide surface can be then coated with a thin amorphous Si layer 7, 10-100 nm thick using HWCVD or another deposition method. Because this layer 7 is amorphous it can be deposited at a very high deposition rate. The amorphous layer 7 can be then coated with a catalyst metal 19, such as Ni or Al, using any suitable several techniques which are discussed above. Then, the layer 7 can be annealed for several hours, such as 3-24 hours, for example 5-10 hours in a silane atmosphere. This anneal can take place in a furnace as a batch process. The silicon growth chamber could also be used to anneal the structure if an external vacuum furnace is not desired for the n+ template layer. During the anneal the metal particles 19 can induce the amorphous film to crystallize with grain sizes of about 10-100 microns in diameter. Then, the epitaxial polysilicon layer 9 can be grown on this large-grained polysilicon template layer 7. The grains of layer 9 can be passivated with hydrogen during the HWCVD process, which allows for microsecond minority carrier lifetimes, similar to bulk Si. The p+ layer 11 can be also deposited by HWCVD without a vacuum break. The method can further comprise depositing the passivation layer 13, such as a silicon nitride layer and at least one electrode 15 in photolithographically defined opening in the passivation layer 13. The electrode 15 can comprise electrically conducting material, such as a metal. For example, the conducting material may comprise Ti, Pt, Au, Pd, Cr, Cu and/or Ag, The electrode can be deposited by any appropriate technique known to ones of ordinary skill in the art including evaporation or sputtering. Then the cell can be completed with traditional ARC and metallization along with a weather sealant joining the cell to the top encapsulation layer, forming a module or submodule component.

An apparatus for manufacturing a thin film polycrystalline Si cell can include a multichamber cluster tool for performing several high vacuum deposition steps. The cluster tool can comprise at least 3 HWCVD chambers (p-type, n-type, and SiN) and a chamber for the metallization (sputtered or evaporated). Redundancy can be preferable so that if one chamber is down the entire system will not be down, for a total of 8 chambers and a load lock. Alternatively, instead of purchasing the substrate already coated, the glass can also be coated in a metallization chamber attached to the cluster tool. Moreover, a scrubber can be used for bulk cleansing the glass substrates.

There are two series of steps in the solar cell manufacturing process during which a vacuum break should be avoided. The first step is the series including the a-Si deposition, metal deposition, and crystallization anneal. This series of steps can involve HWCVD of layer 7 and catalyst metal 19 sputtering or evaporation. If a spin-on technique is used for the metal deposition, then an HF dip can be used to remove any native oxide before the metal deposition. Following the metal deposition, the stack can be immediately annealed before an oxide can have a chance to reform. The second step during which vacuum break should be avoid is between the n layer 9 and p+ layer 11 deposition. Several studies have shown that a vacuum break in the active junction can lower the efficiency of the cell. Since both of these layers 9, 11 are preferably made by HWCVD depositions, accommodating this step can be less complicated.

The active n layer 9 and p+ layer 11 can be deposited in separate HWCVD chambers of a cluster tool. The n layer 9 can be grown epitaxially at a lower growth rate. After this layer 9 is formed, the stack can be transferred into the p+ chamber without a vacuum break. After deposition of the active layers 9, 11, a SiN passivation layer 13 can be deposited.

Most hot-wire CVD systems currently are custom-designed by researchers, but there are several vacuum equipments manufacturers that currently offer HWCVD, equipment including Anelva, sp3, and Elettrorava. HWCVD can have several advantages: it can cause less damage to growing films than plasma enhanced chemical vapor deposition (PECVD), it can offer high deposition rates, and can be more efficient in the decomposition of precursors. It can be also potentially scaleable to very large areas. Chemical precursors for HWCVD deposition can include silane, phosphine, trimethylboride or diborane, and ammonia.

The manufacturing apparatus or system may also include in-line characterization devices to develop a highly reliable process. Ellipsometry for measuring thickness and optical properties can be one example for a possible in-situ measurement. Moreover, device characterization tools to measure efficiency and also individual material properties like lifetime can be beneficial. An example can be radio-frequency (RF) photoconductive decay lifetime analysis, which can be done in-line at a contactless measurement station.

The cost per square meter of the active Si layers at 75% utilization can be estimated to be approximately $1.30/m², based on the calculations for amorphous Si cells, see R. Arya and M. S. Kessler, Study of Potential Cost Reductions Resulting from Super-Large-Scale Manufacturing of PV Modules, NREL Report for Subcontract Subcontract No. ADJ-3-33631-01, 2004, incorporated herein by reference in its entirety. At 14% efficiency the cost per watt at the panel level can be $0.30/W at very high volume production. This can be a large cost reduction compared to Si wafers which can cost approximately $1.75-$2.50/W.

According to a study of the potential cost reductions resulting from a 2.1-3.6 GW factory of PV modules, a dedicated low-Fe sheet glass facility can produce sheet glass with a textured SnO₂ coating for $4.62 per sq. meter, see R. Arya and M. S. Kessler, Study of Potential Cost Reductions Resulting from Super-Large-Scale Manufacturing of P V Modules, NREL Report for Subcontract Subcontract No. ADJ-3-33631-01, 2004, incorporated herein by reference in its entirety. However, as described above, the SnO₂ does not need to be textured as the HWCVD grown film roughens as it grows, nor does the glass need to be low-Fe if it is a substrate rather than the traditional superstrate or even stainless steel.

Large-grained polycrystalline silicon can be a promising direction for thin film photovoltaics. At the current stage of development, the cost of a module can be reduced by at least ⅓ of current cost. Further development can easily bring down production costs to $1.00 per watt.

The invention can be further illustrated by, though in no way limited to, the following example.

Template fabrication. To fabricate SNSPE templates, 60 μL of a colloidal “ink” containing 20 μg nickel nanoparticles 1 mL of isopropanol is spun for 20 seconds at 1500 rpm onto a 100 nm thick amorphous Si layer on SiO₂, leaving randomly distributed array of nanoparticles. The subsequent anneal is performed at 485° C. in vacuum or in silane containing atmosphere. The thicknesses of the amorphous silicon layer and the anneal durations are summarized in Table I below.

TABLE 1

| Example | Anneal | Layer | Time at | % |
|---|---|---|---|---|
| # | Ambient | Thickness | 485 C. | Crystalline |
| 1 | Silane | 100 nm | 3 h 35 m | 27.98% |
| 2 | Silane | 200 nm | 5 h 15 m | 88.57% |
| 3 | Silane | 500 nm | 5 h 15 m | 23.77% |
| 4 | Vacuum | 100 nm | 3 h 57 m | 8.2% |
| 5 | Vacuum | 200 nm | 5 h 35 m | 0% |
| 6 | Vacuum | 500 nm | 5 h 35 m | 14.27% |

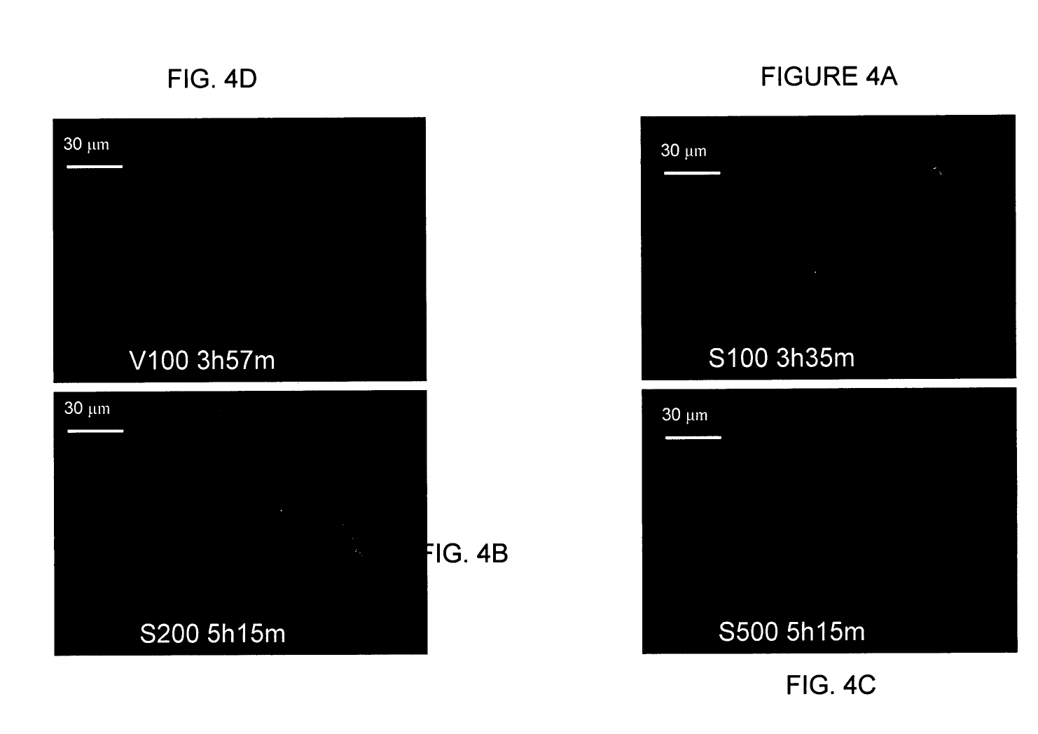

Optical microscopy. Crystallization of the Si films of examples 1-4 was first observed by optical microscopy (FIGS. 4A-4D, respectively). The phase transformation from amorphous to crystalline results in a change of the optical absorption in the Si film, which is expressed in a color change. In FIGS. 4A-D, S stands for silane ambient, V for vacuum. The number following the letter is the nominal thickness of the template layer, followed by the time of the anneal.

Raman determined crystallinity. The crystallinity of Si films annealed in vacuum and in silane containing atmosphere was obtained by comparing intensities of characteristic Raman modes at ˜520 cm⁻¹ and ˜480 cm⁻¹ of crystalline and amorphous silicon respectively. The results summarized in Table 1 indicate that films annealed in a silane containing atmosphere have a higher degree of crystallinity than films annealed in vacuum.

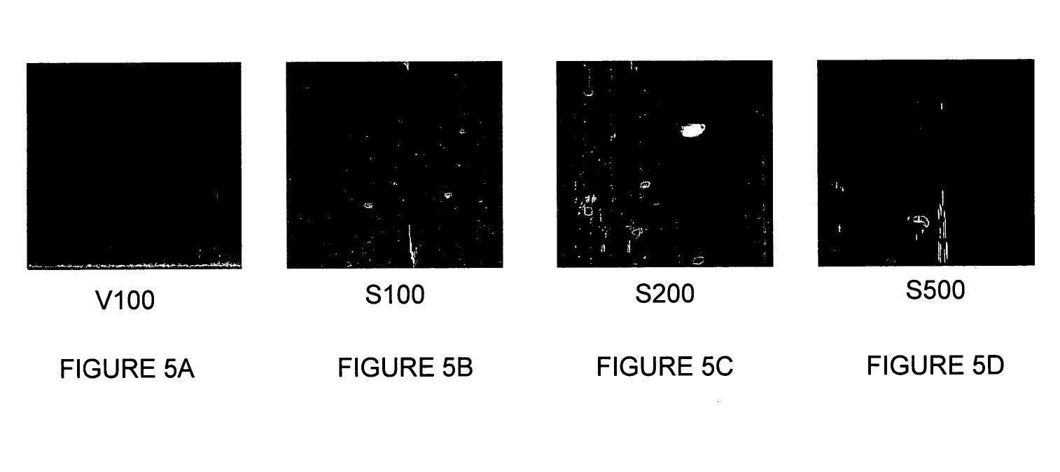

Atomic Force Microscopy. Atomic Force Microscopy was used to characterize the surface roughness of a series of films annealed in vacuum and in silane containing atmosphere. FIGS. 5A-5D, respectively, present 10×10 micron AFM scans for 100 nm thick film annealed in vacuum (V100) and 100, 200, and 500 nm thick SNSPE films annealed in a silane containing atmosphere (S100, S200 and S500, respectively). Table 2 presenting AFM measured roughness of the characterized films shows that films annealed in silane containing atmosphere have higher roughness than vacuum annealed films. The relatively high roughness of silane annealed films can allow one to use a thinner SNSPE film as a template layer 7.

TABLE 2

| FIG. 5 label | RMS (A) | Avg. rough. (A) | Anneal Time |
|---|---|---|---|
| S500 | 44.4 | 34.8 | 6 h 43 m |
| S200 | 45 | 35.4 | 6 h 43 m |
| S100 | 42.9 | 33.8 | 5 h 3 m |
| V100 | 8.3 | 6.86 | 6 h 35 m |

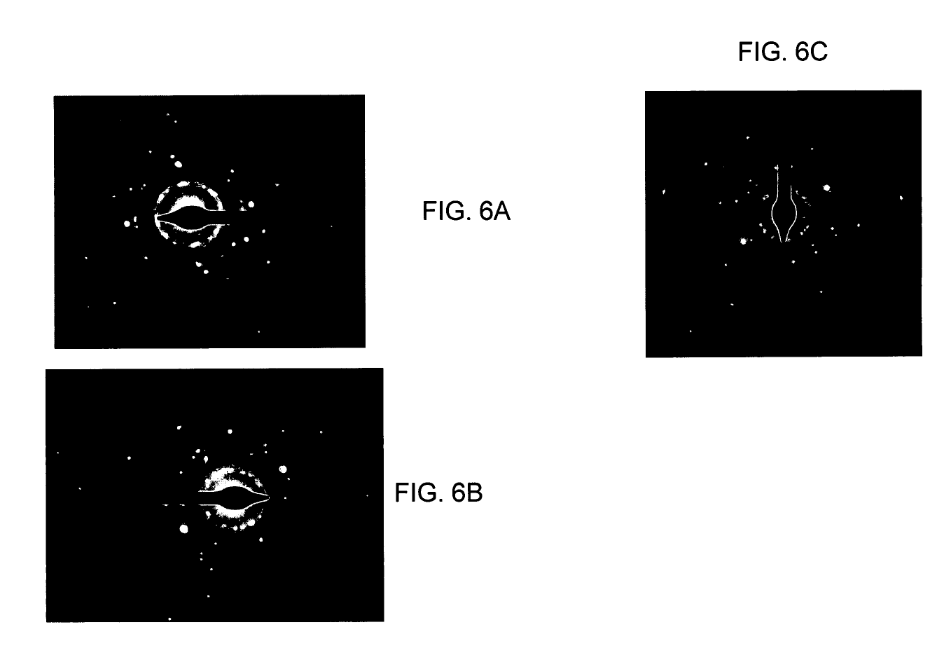

Selective Area Diffraction (SAD) is a technique which provides information about crystallinity in a TEM sample. FIGS. 6A-C provide SAD patterns of SNSPE templates annealed in silane containing atmosphere (FIGS. 6A, 6B) and in vacuum (FIG. 6C) and show the structural equivalence.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited in this specification are incorporated herein by reference in their entirety.

What is claimed is:

1. A silicon structure, comprising:
a selective nucleating single phase epitaxial (SNSPE) template polysilicon layer containing crystallization catalyst residue; and
a hot wire chemical vapor deposited (HWCVD) epitaxial polysilicon layer epitaxially grown on said template layer;
wherein said silicon structure satisfies at least one of the following: 1) a thickness of the SNSPE template layer is less that about 60 nm; 2) a thickness of the HPCVD layer is greater than about 60 nm.

2. The silicon structure of claim 1, wherein the thickness of the SNSPE template layer is less that about 60 nm.

3. The silicon structure of claim 1, wherein the thickness of the HPCVD layer is greater than about 60 nm.

4. The silicon structure of claim 1, wherein the thickness of the SNSPE template layer is less that about 60 nm and the thickness of the HPCVD layer is greater than about 60 nm.

5. The silicon structure of claim 1, wherein said crystallization catalyst residue comprises Ni, Fe, Co, Ru, Rh, Pd, Os, Ir, Pt, Cu, Au, In, Ge, Al or combinations thereof.

6. The silicon structure of claim 1, wherein the template layer has average grain size ranging from about 1 micron to about 100 microns.

7. The silicon structure of claim 1, wherein said SNSPE template layer is grown on a substrate comprising at least one material with a softening temperature below about 550° C.

8. The silicon structure of claim 1, wherein an average roughness of said HWCVD film is more than about 20 Å.

9. A solar cell comprising the silicon structure of claim 1.

10. The solar cell of claim 9, further comprising:
a transparent substrate having a softening temperature below about 550° C.;
a transparent electrode located between the substrate and the template layer;
a second epitaxial polysilicon layer located on the HWCVD layer, wherein the second epitaxial polysilicon layer has an opposite conductivity type to that of the HWCVD layer; and
a second electrode over the second epitaxial polysilicon layer.

11. An electronic device comprising the silicon structure of claim 1.

12. A method of making a polysilicon layer, comprising:
providing a first layer comprising an amorphous silicon or a polysilicon layer containing a crystallization catalyst or in contact with a crystallization catalyst; and
annealing the first layer in a silicon containing atmosphere to at least partially crystallize the first layer.

13. The method of claim 12, wherein said silicon containing atmosphere comprises a silane atmosphere.

14. The method of claim 12, wherein said annealing is performed at a temperature below about 600° C.

15. The method of claim 14, wherein said annealing is performed at a temperature between 450 and 550° C. for 5 to 24 hours on an amorphous silicon first layer to crystallize at least 50% of the first layer.

16. The method of claim 14, wherein the first layer contacts nickel nanoparticle crystallization catalyst prior to the step of annealing.

17. The method of claim 12, further comprising epitaxially growing a second polysilicon layer on the first polysilicon layer after the step of annealing.

18. The method of claim 17, wherein said growing is performed by a hot wire chemical vapor deposition.

19. The method of claim 18, wherein:
the first and the second layers are located in a solar cell;
a thickness of the first layer is less that about 60 nm; and
a thickness of the second layer is greater than about 60 mm.

20. The method of claim 19, further comprising epitaxially growing a third polysilicon layer and the second polysilicon layer, wherein the third layer has an opposite conductivity type to the first layer.
